(19) United States
(12) Patent Application Publication
(10) Pub. No.: US 2013/0214033 A1
(43) Pub. Date: Aug. 22, 2013

(54) METHOD FOR JOINING A FIRST ELECTRONIC COMPONENT AND A SECOND COMPONENT

(71) Applicant: Vectron International GmbH, (US)

(72) Inventors: Matthias KLEIN, Berlin (DE); Richard GRÜNWALD, Potsdam (DE); Bert WALL, Potsdam (DE)

(73) Assignee: Vectron International GmbH, Teltow (DE)

(21) Appl. No.: 13/772,388

(22) Filed: Feb. 21, 2013

(30) Foreign Application Priority Data
Feb. 22, 2012 (DE) 10 2012 202 727.0

(51) Int. Cl. H05K 13/04

(52) U.S. Cl. CPC H05K 13/04
USPC 228/121; 228/124.5

(57) ABSTRACT

This invention relates to a method for joining a first electronic component with a second component using an active brazing alloy. It is the object of this invention to provide a simplified method for achieving a reliable, stress-reduced joint of a high-temperature stable piezoelectric oxidic mono-crystal. According to the method of the invention, a first component (1, 1a, 1b) and a second component (1, 2, 2a, 2b, 4, 4a) are provided, wherein the first component (1, 1a, 1b) includes a piezoelectric oxidic mono-crystal, wherein the piezoelectric oxidic mono-crystal of the first component (1), is joined with the second component (1, 2, 2a, 2b, 4, 4a) using an active brazing alloy (3), wherein the active brazing alloy (3) directly contacts the piezoelectric oxidic mono-crystal of the first component (1, 1a, 1b).

### RELATED APPLICATION

This application claims the benefit of priority of German Patent Application No. 10 2012 202 727.0 filed Feb. 22, 2012, the contents of which are incorporated herein by reference in their entirety.

### FIELD AND BACKGROUND OF THE INVENTION

This invention relates to a method for joining a first electronic component and a second component using an active brazing alloy; in particular, this invention relates to a stress-reduced joining method using active brazing of piezoelectric mono-crystals for high-temperature applications.

A standard method for bonding surfaces of components including a piezoelectric mono-crystal is the use of a suitable, mostly non-conducting adhesive that is deposited onto the substrate or another electronic component prior to assembly of the electronic component and eventually cures. However, the use of adhesives is not suitable if the component is used at high temperatures of more than 400° C.

Another method of joining components that include piezoelectric mono-crystals involves the use of brazing alloys in the form of a paste or a preform. A disadvantage of this method is that it requires coating of both the electronic component and the substrate with a surface that can be wetted by the brazing alloy having a suitable adhesive and barrier layer. An integral joint between the one electronic component and the other electronic component or substrate is created after melting the brazing alloy.

Another method of joining components that include piezoelectric mono-crystals involves the use of sintering pastes made, for example, of silver. It is a disadvantage of this method that it requires coating of both the electronic component and the substrate with a suitable metal film. The joint is mostly formed under pressure at an elevated temperature.

Another method of joining components that include piezoelectric mono-crystals involves the use of metal/glass or glass adhesives. The material is deposited to the substrate or another electronic component or to both sides prior to assembly of the electronic component. The joint is mostly formed under pressure at a high temperature, sometimes also in an oxygen-containing atmosphere.

The methods described above are either unsuitable for the assembly of electronic components that will later be used at operating temperatures of more than 400° C. or they require additional process steps for applying suitable, high-temperature stable metal films.

Since the function of components with piezoelectric mono-crystals can be adversely influenced by thermo-mechanically induced stress, a stress-reduced joining method must be developed.

One of the objects of this invention is to provide a simplified method for achieving a reliable, stress-reduced joint of a high-temperature stable piezoelectric oxidic mono-crystal. Another object of this invention is to provide a reliable stress-reduced joint of a high-temperature stable piezoelectric oxidic mono-crystal with another component that can be produced cost-efficiently.

A stress-reduced joint between a first component with a piezoelectric oxidic mono-crystal and a second component is achieved, according to the invention, by bonding the piezoelectric oxidic mono-crystal of the first component with the second component using an active brazing alloy, that is, by brazing, wherein the active brazing alloy directly contacts the piezoelectric oxidic mono-crystal of the first component. In this way, the components can advantageously be used at high temperatures over 400° C.

It is preferred that the active brazing alloy is directly deposited onto the piezoelectric oxidic mono-crystal of the first component. Alternatively, it is preferred that the piezoelectric oxidic mono-crystal is directly deposited onto the active brazing alloy. In accordance with the invention, a joining method is proposed for assembling high-temperature stable piezoelectric oxidic mono-crystals in which the piezoelectric oxidic mono-crystal of the electronic component can be joined without an additional coating (that is, without additional metalization) with a substrate or other electronic component (which may also comprise a piezoelectric oxidic mono-crystal). For this purpose, it is preferred that an active brazing alloy of any desired composition is deposited in the form of a paste or preform onto the substrate or electronic component.

It is preferred that the second component includes a ceramic, a metal, or a piezoelectric oxidic mono-crystal.

It is preferred that the active brazing alloy is deposited with a texture. It is preferred that the active brazing alloy is asymmetrically textured relative to the piezoelectric oxidic mono-crystal of the first component. It is preferred that the piezoelectric oxidic mono-crystal of the first component is shaped like a plate with at least two opposing lateral surfaces and that the active brazing alloy is provided in the region of one of the two lateral surfaces only.

It is preferred that the piezoelectric oxidic mono-crystal of the first component includes an acoustically active section in which an electrically conductive structure is deposited onto the mono-crystal and a contacting section, and that the active brazing alloy is provided in the contacting section only.

It is preferred that the substrate surface and/or the surface of the component is/are textured. It is preferred that the brazing alloy and/or the surfaces is/are electrically connected in addition to the mechanical joint by structuring via contacts provided on the component or substrate.

It is preferred that a hermetic seal of the substrate material that functions as a package is provided by a lid made of ceramic or metal. It is preferred that a second active brazing alloy used for hermetically sealing the package with a lid has a lower melting point than the active brazing lot used for joining the electronic component and the substrate.

It is preferred that, before brazing, a height profile is inserted into the surface of the piezoelectric oxidic mono-crystal facing the active brazing alloy. It is preferred that, before brazing, a height profile is inserted into the surface of the second component facing the active brazing alloy. The height profile preferably comprises a recess in an area outside the active brazing alloy.

An active brazing alloy is a brazing alloy that contains a reactive component. If a piezoelectric oxidic mono-crystal is brazed, the reactive component is a component that has a sufficiently strong affinity to the piezoelectric oxidic mono-crystal, e.g. to oxygen. Affinity is strong enough if the formation enthalpy of the reactive component is smaller than the formation enthalpy of the mono-crystal under the prevailing brazing conditions. Brazing conditions include in particular the brazing temperature and the pressure during brazing of the substances involved in the reaction. The reactive component in the active brazing alloy allows wetting of the mono-crystal surface to be brazed. Wetting is a prerequisite for a brazed joint.

The first electronic component is provided, according to the invention, on a high-temperature stable, piezoelectric oxidic mono-crystal, such as stoichiometric lithium niobate or langasite. The first electronic component is joined with a substrate or another electronic component across an entire flat surface or a part thereof. The substrate may consist, for example, of a ceramic, a metal or a high-temperature stable piezoelectric oxidic mono-crystal.

It is preferred that a piezoelectric oxidic mono-crystal is used that is stable at temperatures of more than 400° C. Examples of preferred, suitable high-temperature stable piezoelectric oxidic mono-crystals are listed in Table 1.

TABLE 1
Examples of preferred high-temperature
stable piezoelectric mono-crystals

| Description | Examples |
|---|---|
| LGX family: Langasite, | La₃Ga₅SiO₁₄, La₃Ga_{5.5}Nb_{0.5}O₁₄, |
| langanite, langatate, or their | La₃Ga_{5.5}Ta_{0.5}O₁₄, La₃Ga_{5.25}Ta_{0.25}Si_{0.5}O₁₄, |
| substitution isomorphs | La₃Ga₅Zr_{0.5}Si_{0.5}O₁₄ |
| Structural isomorphs of the | Sr₃TaGa₃Si₂O₁₄, Sr₃NbGa₃Si₂O₁₄, |
| LGX family of the general | Ca₃TaGa₃Si₂O₁₄, Ca₃TaAl₃Si₂O₁₄ |
| formula A₃BC₃Si₂O₁₄ | |
| Rare earth calcium | GdCa₄O(BO₃)₃, YCa₄O(BO₃)₃, |
| oxyborates | LaCa₄O(BO₃)₃ |
| Stoichiometric lithium | LiNbO₃ |
| niobate | |
| Gallium orthophosphate | GaPO₄ |

Electronic components based on a high-temperature stable piezoelectric oxidic mono-crystal include, for example, surface acoustic wave (SAW) elements or bulk acoustic wave (BAW) elements.

It is decisive for selecting the active brazing alloy for contacting a high-temperature stable piezoelectric oxidic mono-crystal to use a stress-reduced joint that is as ductile as possible and adjusted in its coefficient of thermal expansion, otherwise the functioning of the component cannot be ensured. It was surprisingly found that an active brazing alloy based on an Ag/Cu alloy meets the requirement of stress-reduced contacting for the assembly of piezoelectric mono-crystals particularly well.

To achieve stress-reduced contacting of the electronic component, it may also be necessary to mold the connector contacts accordingly or to arrange them as a lateral contacting section. Joining by active brazing is preferably performed under pressure and high temperature in a vacuum process or an inert gas atmosphere.

According to another aspect of the invention, an electronic component is disclosed that includes a piezoelectric oxidic mono-crystal, wherein the piezoelectric oxidic mono-crystal of the first component is connected to a second component using an active brazing alloy.

It is preferred that the active brazing alloy directly contacts the piezoelectric oxidic mono-crystal of the first component.

It is preferred that the first component is designed as a surface acoustic wave or bulk acoustic wave component.

It is preferred that the piezoelectric oxidic mono-crystal consists of langasite, langanite, langatate, lanthanide calcium oxyborate, lithium niobate, or gallium orthophosphate. It is preferred that the second component includes a ceramic, a metal, or a piezoelectric oxidic mono-crystal.

It is preferred that the active brazing alloy has a texture. The active brazing alloy is preferably textured such that it does not spread under the entire surface of the piezoelectric oxidic mono-crystal.

It is preferred that the active brazing alloy is asymmetrically textured relative to the piezoelectric oxidic mono-crystal of the first component.

It is preferred that the piezoelectric oxidic mono-crystal of the first component is shaped like a plate with at least two opposing lateral surfaces. It is preferred that the active brazing alloy is provided in the region of one of the two lateral surfaces only. In this way, fixation of the mono-crystal by the active brazing alloy is largely free floating (similar to a jumping board), wherein the joint between the active brazing alloy and the mono-crystal is made at one side of the mono-crystal only. It is preferred in this embodiment that the active brazing alloy wets less than 50%, more preferred less than 30%, and even more preferred less than 20% of the mono-crystal.

It is preferred that the piezoelectric oxidic mono-crystal of the first component includes an acoustically active section in which an electrically conductive structure is deposited onto the mono-crystal and a contacting section that is separate thereof. It is preferred that the active brazing alloy is provided in the contacting section only.

It is preferred that the surface of the piezoelectric oxidic mono-crystal of the first component that faces the active brazing alloy comprises a recess. It is preferred that the surface of the piezoelectric oxidic mono-crystal of the second component that faces the active brazing alloy comprises a recess.

It is preferred that the active brazing alloy preferably is a silver-copper alloy.

The method according to the invention has numerous advantages compared to prior art:
Selection of a suitable active brazing alloy and the type of contacting allow stress-reduced assembly, which is imperative for the flawless functioning of an electronic component based on a piezoelectric oxidic mono-crystal to be applied at temperatures over 400° C.;
No additional high-temperature metal film is required on the electronic component or the substrate, which reduces the manufacturing effort considerably;
The active brazing alloy can be processed using low-cost standard methods as a brazing paste or preform;
The elements that are joined are not subject to oxidation since brazing takes place in a vacuum or an inert gas atmosphere; and
Spatial division of the component into a lateral contacting section and an acoustically active section results in decoupling of the thermo-mechanical stress induced by contacting and acting adversely during operation at temperatures over 400° C.

### BRIEF DESCRIPTION OF THE DRAWINGS

The method according to the invention of reliably joining an electronic component based on high-temperature stable piezoelectric oxidic mono-crystals is explained below with reference to the following schematic drawings.

Wherein:

FIG. 1 shows a flat surface joint according to the invention of an electronic component and a substrate using an active brazing alloy;

FIG. 2 shows a flat surface joint according to the invention of an electronic component and another electronic component using an active brazing alloy;

FIG. 3a shows a textured deposit according to the invention of an active brazing alloy for connecting the electronic component mechanically and/or electrically with the substrate;

FIG. 3b shows a textured deposit according to the invention of an active brazing alloy for making a mechanical and/or electrical connection between an electronic component and a substrate by utilizing modified substrate or component surfaces;

FIG. 4 shows an electronic component mounted in a package with a flat surface joint using an active brazing alloy, contacted using wire bonds, and sealed hermetically with a lid using a second active brazing alloy;

FIG. 5a shows a textured one-sided deposit according to the invention of an active brazing alloy for mechanically joining the electronic component and the substrate while electrical contact is made using wire bonds;

FIG. 5b shows a textured one-sided deposit according to the invention of an active brazing alloy for mechanically joining the electronic component and the substrate, wherein the component comprises a modified component surface and is electrically contacted using wire bonds;

FIG. 6 shows a top view of the electronic component according to the invention, the surface of which is divided into two sections, a contacting section and an acoustically active section; and

FIG. 7 shows an electronic component according to the invention mounted one-sided in a package using an active brazing alloy, contacted electrically using wire bonds, and sealed hermetically with a lid using a second active brazing alloy.

### DESCRIPTION OF SPECIFIC EMBODIMENTS OF THE INVENTION

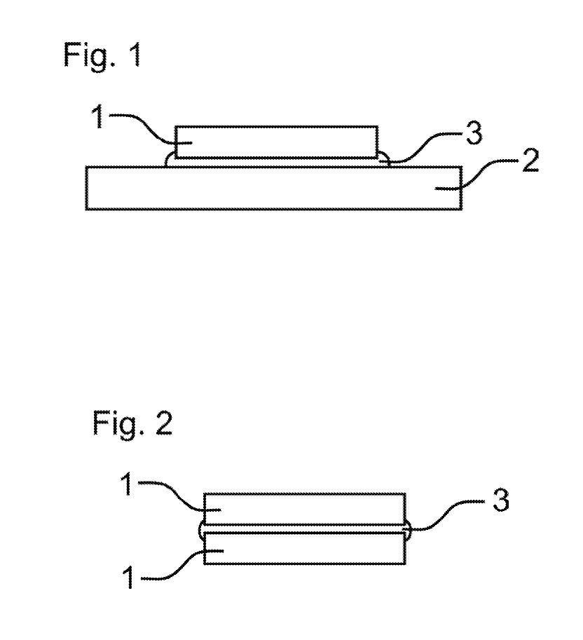

FIGS. 1 and 2 show the joint according to the invention of an electronic component 1 with a substrate 2 or another electronic component 1, respectively. Accordingly, the active brazing alloy 3 can be deposited flatly onto the substrate 2 (FIG. 1) or another electronic component (FIG. 2) by dispensing, stencil or silk-screen printing or using preforms if the components are sufficiently small, preferably having an edge length of less than 1.5 mm (if more edges are involved, this length refers to the longest edge). After positioning, the joint is preferably produced by brazing under pressure and high temperature in a vacuum process or an inert gas atmosphere. It is preferred that the electronic component 1 is a SAW or BAW component (such as a SAW resonator).

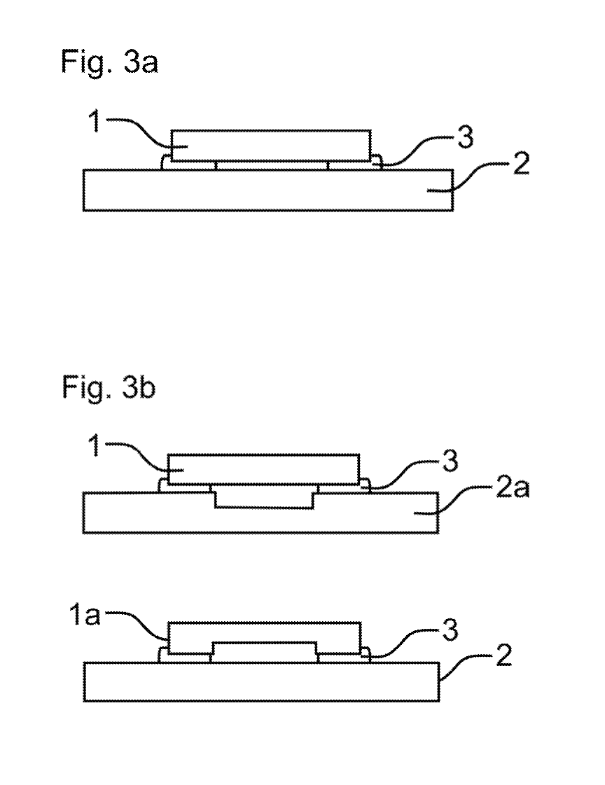

According to another embodiment, the active brazing alloy 3 can also be deposited with a texture. When the components 1 are getting bigger, preferably at an edge length greater than or equal to 1.5 mm, the mechanical stress that acts on the component 1 with a flat-surface joint will increase due to differing coefficients of thermal expansion of the component 1, the active brazing alloy 3, and the substrate 2 and thus adversely impact its mechanical and, consequently, its electrical properties or result in cracking. According to the invention, the active brazing alloy 3 is deposited with a texture to reduce stress. The texturing can be achieved by targeted depositing of the brazing alloy 3 (FIG. 3a) or by modifying the substrate surface 2a or the component surface 1a accordingly (FIG. 3b). It is preferred that the marginal section of the component 1 or 1a, respectively, is at least partially in direct contact with the active brazing alloy 3. The active brazing alloy 3 or the component 1a, respectively, are preferably textured such that sections without active brazing alloy 3 are provided in a central area of the component 1 or 1a, respectively.

Furthermore, the textured joint of the component 1 is not just a type of mechanical fixation like a “chip on board” assembly (the active side of the component is bonded to the substrate and then contacted using wire bonds) but at the same time involves electrical contracting, i.e. a “flip chip” assembly (the active side of the component faces the substrate) if the respective electrical terminals are provided on the component 1 and the substrate 2.

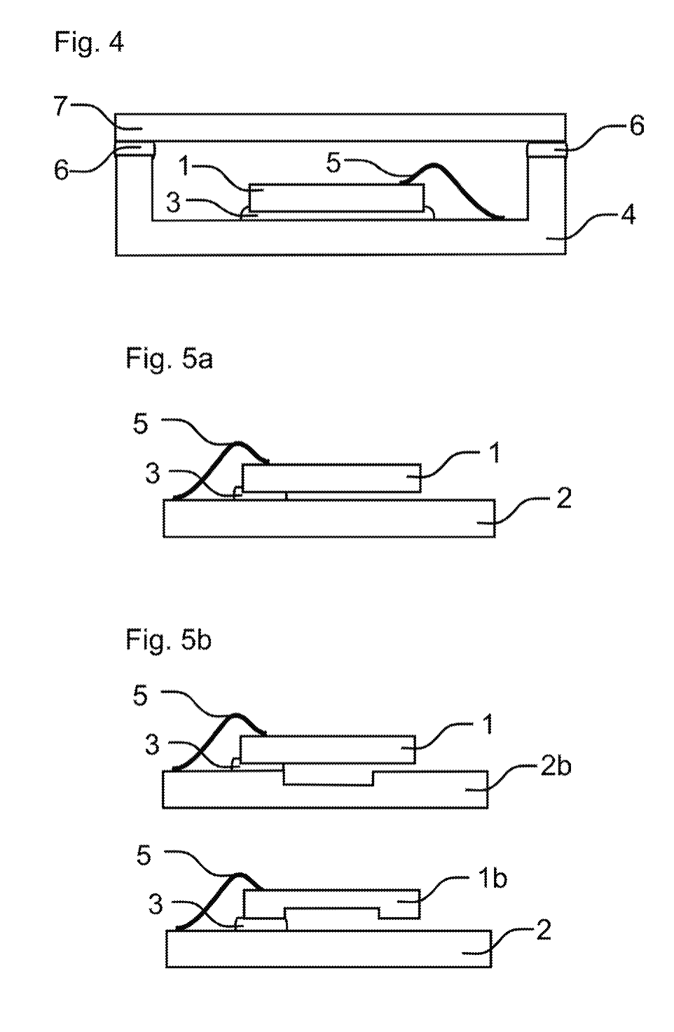

According to another embodiment (FIG. 4), a package 4 is used as the substrate for the component 1. The package 4 can be hermetically sealed after assembling the component 1 using an active brazing alloy 3 and electrical contacting 5 of the component 1 using wire bonding by applying a lid 7 using a second active brazing alloy 6 with a lower melting point. The second active brazing alloy 6 can be deposited by dispensing, stencil or silk screen printing, or using a preform. After positioning the lid 7, the joint is preferably produced by brazing under pressure and high temperature in a vacuum process or an inert gas atmosphere. An advantage of this method is an oxygen-free atmosphere that can then be established in the package.

According to another embodiment (FIG. 5a), the active brazing alloy 3 can be deposited with a texture on one side only (with reference to the component 1, preferably a SAW component) onto the substrate 2. In addition, the substrate surface 2b or the component surface 1b can be modified to improve the texturing of the active brazing alloy 3 (FIG. 5b). The substrate surface 2b or the component surface 1b, respectively, is preferably modified by introducing a recess. The electrical contacting 5 of the component 1 is performed using wire bonds.

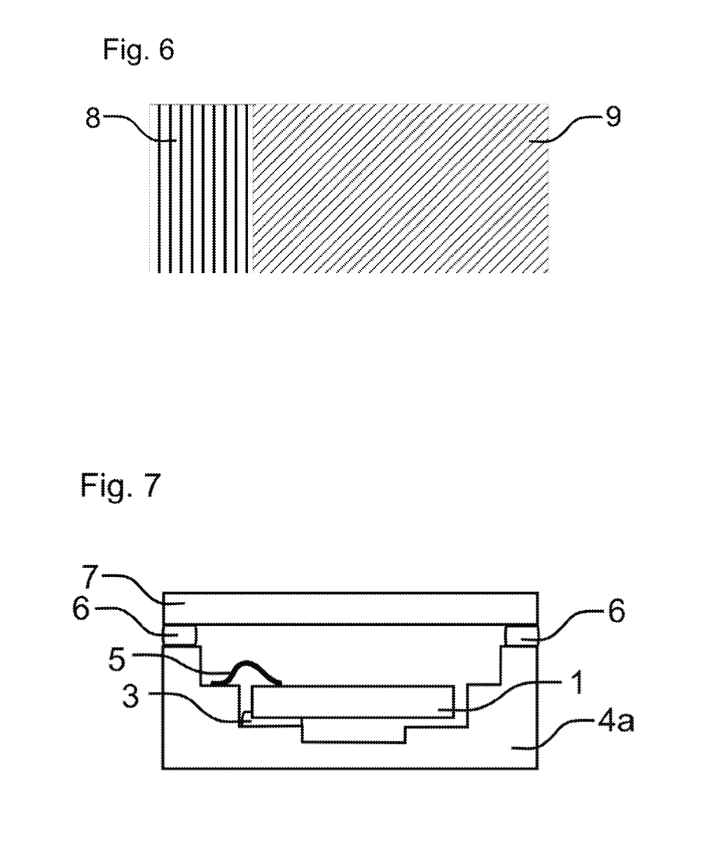

According to another embodiment, the design of the component 1 can be divided into two sections: a lateral contacting section 8 and an acoustically active section 9 (FIG. 6). The acoustically active section is the region of the piezoelectric oxidic mono-crystal in which surface acoustic or bulk acoustic waves are excited or reflected or spread. The lateral contacting section takes up less than 50%, preferably less than 30%, and more preferably less than 20% of the component area. In the case of a SAW component of the chip on board assembly type, the top side of the contacting section 8 is equipped with terminals for wire bonding 5 and the bottom side has no additional metal film for bonding using the active brazing alloy 3. In the case of a SAW component of the flip chip assembly type, metal terminals are required in the contacting section for electrical and, in most cases, also mechanical bonding using the active brazing alloy 3. The goal is to provide spatial separation of the contacting section 8 and the active section 9 so that thermo-mechanically induced tensions remain limited to the contacting section and will influence the functioning of the component 1 to a minor extent only or not at all.

In another embodiment (FIG. 7), a package 4a, for example HTCC, is used as the substrate. In the package 4a, the active brazing alloy 3, e.g. a silver-copper alloy with an added approximately 3% by weight of titanium is deposited on one side. To achieve a reproducible molding of the contact point for assembling the component 1, e.g. a langasite sensor chip, the contact point in the package 4a is on three sides bordered by the side walls of the package 4a itself and towards the interior by a recess in the package bottom.

According to a particularly preferred embodiment, the package 4a comprises a recess that is dimensioned such that the piezoelectric oxidic mono-crystal (component 1) can be inserted into the recess, i.e. the recess is slightly larger than the mono-crystal. According to the invention, another (second) recess with which a defined contact point in the package 4a can be implemented is provided in the recess that receives the mono-crystal. The contact point is thus on one side bordered by the recess. It is preferred that the defined contact point is bordered on (up to) three more sides by the side walls of the package 4a. The component 1 is assembled using the active brazing alloy 3, and electrical contacting 5 of the component is performed by gold wire bonding. The package 4a can then be hermetically sealed using a second active brazing alloy 6, for example, a silver-copper-indium alloy with an addition of about 1.5 percent by weight of titanium and with a lower melting point for attaching a lid 7, e.g. a HTCC lid. The second active brazing alloy 6 can be deposited by dispensing, stencil or silk screen printing, or using a preform. After positioning the lid 7, the joint is preferably produced by brazing under pressure and high temperature in a vacuum process or an inert gas atmosphere. An advantage of this method is an oxygen-free atmosphere that can then be established in the package.

What is claimed is:

1. A method for joining a first electronic component with a second component comprising the following steps:
providing the first component and the second component, wherein the first component includes a piezoelectric oxidic mono-crystal, wherein:
the piezoelectric oxidic mono-crystal of the first component is joined with the second component using the active brazing alloy, wherein the active brazing alloy directly contacts the piezoelectric oxidic mono-crystal of the first component.

2. The method according to claim 1, wherein:
a surface acoustic wave component or a bulk acoustic wave component is used as the first component.

3. The method according to claim 1, wherein:
langasite, langanite, langatate, a compound that is a substitution isomorph or structural isomorph of the LGX family, lanthanide calcium oxyborate, lithium niobate, or gallium orthophosphate is used as the piezoelectric oxidic mono-crystal of the first component.

4. The method according to claim 1, wherein:
the second component includes a ceramic, a metal, or a piezoelectric oxidic mono-crystal.

5. The method according to claim 1, wherein:
the active brazing alloy (3) is deposited with a texture.

6. The method according to claim 5, wherein:
the active brazing alloy is textured asymmetrically relative to the piezoelectric oxidic mono-crystal of the first component.

7. The method according to claim 6, wherein:
the piezoelectric oxidic mono-crystal of the first component is shaped like a plate with at least two opposing lateral surfaces, wherein the active brazing alloy is provided in the region of one of the two lateral surfaces only.

8. The method according to claim 2, wherein:
the piezoelectric oxidic mono-crystal of the first component includes an acoustically active section and a contacting section wherein the active brazing alloy and/or at least one wire bond is/are provided in the contacting section only.

9. The method according to claim 1, wherein:
before brazing, a height profile is inserted into the surface of the piezoelectric oxidic mono-crystal of the first component that faces the active brazing alloy, and/or that, before brazing, a height profile is inserted into the surface of the second component that faces the active brazing alloy.

10. The method according to claim 1, wherein:
a silver-copper alloy is used as the active brazing alloy.

11. The method according to claim 1, wherein:
the piezoelectric oxidic mono-crystal is designed as a sensor with an operating temperature above 400° C.
